(19) United States
(12) Patent Application Publication
(10) Pub. No.: US 2007/0253161 A1
(43) Pub. Date: Nov. 1, 2007

(54) Fan of heat sink

(75) Inventors: Hung-Sheng Liu, Hsin-Chuang (TW); Jui-Hung Cheng, Hsin-Chuang (TW); Yi-Chieh Chen, Hsin-Chuang (TW)

Correspondence Address: Asia Vital Components Co., Ltd., P.O. BOX 1-195, YUNG HO, TW

(73) Assignee: ASIA VITAL COMPONENTS CO., LTD., HSIN-CHUANG (TW)

(21) Appl. No.: 11/414,480

(22) Filed: May 1, 2006

(51) Int. Cl. H05K 7/20

(52) U.S. Cl. 361/695

(57) ABSTRACT

A heat sink comprising an open frame including air inlets on a top side and a rotatable fan having a plurality of blades is provided. The heat sink is installed in the frame. The frame has pluralities of supporting elements and ribs positioned between two adjacent supporting elements. The supporting elements and ribs correspond to each other to form multiple side air inlets. The operation of the fan is capable of drawing a large volume of the air into the open frame via the top side and side air inlets. The flange of the blades is parallel to the inner curved side of the ribs when the blades pass by the ribs so that a large volume of air is guided into the frame to enhance the heat dissipation effect. This may also maintain an optimum static pressure and substantially reduce the noise level during the operation of the fan.

### BACKGROUND OF THE INVENTION

1. Field of the Invention

The present invention relates to a heat sink, and more particularly to a heat sink capable of axially drawing air and reducing air resistance to reduce the noise during the operation thereof.

2. Description of the Related Art

Referring to FIG. 1, a conventional heat sink 1 comprises a frame 11 and a fan 12 rotatably disposed in the frame 11. The fan 12 comprises a hub 121 with a height higher than that of the frame 11 and a plurality of blades 122 alternately positioned around the outer periphery of the hub 121, wherein the blades protrude out of the frame 11. The height of the frame 11 is lower than that of the blades 122 to increase the contact surface area between the sidewall of blades 122 and the outside air to facilitate entrance of the air from outside via the top air and sides of the frame 11 and thereby increase the volume of air entering into the frame 11 to enhance the heat dissipation effect.

When the contact surface area between the sidewall of blades 122 and the inlets air is increased, the air from outside enters via the space between the sidewall of the blades 122 and the top side of the frame 11. Even though the volume of the incoming air into the frame is increased, the poor design of the top of the frame 11 blocks or resist the air entering via the space between the top side of the frame 11 and the sidewall of the blades 122. Thus, the air cannot smoothly enter into the frame 11. Therefore, not only the volume of air entering into the frame 11 is limited but also the static pressure is low and noise level is high during the operation of the fan 12.

### SUMMARY OF THE INVENTION

Accordingly, in the view of the foregoing, the present invention provides a heat sink capable of drawing increased volume of air via the top and side while maintaining an optimum static pressure. Thus, the noise level during the operation of the heat sink may be reduced.

According to an aspect of the present invention, the heat sink comprises a frame including air inlets and a fan rotatably disposed in the frame. The frame comprises a plate, a plurality of supporting elements alternately positioned in the flange of the plate and a plurality of ribs positioned between the two supporting elements to form the air inlets. Each rib has an inner curved side. The supporting elements and the ribs correspond to each other to form a plurality of side air inlets. The fan comprises a rotatable hub axially positioned on the plate and a plurality of blades alternatively positioned around the outer periphery of the hub. The flange of the blades is substantially parallel to the inner curved side of the rib when the blades pass by the ribs.

The present invention is more advantageous in having the ribs correspond to the supporting elements to form a plurality of air inlets so that the rotation of the fan may draw a substantially large volume of air from outside via the top air inlets and the side air inlets into the frame and thereby effectively increase the volume of incoming air as well as substantially reduce the noise level during the operation of the fan. The flange of the blades is substantially parallel to the inner curved side of the rib when the blades pass by the ribs so as to facilitate passage of the incoming air and substantially increase the volume of incoming air to effectively enhance the heat dissipation effect as well as maintain optimum static pressure and reduce the noise level during the operation of the fan.

### BRIEF DESCRIPTION OF THE DRAWING

For a more complete understanding of the present invention, reference will now be made to the following detailed description of preferred embodiments taken in conjunction with the following accompanying drawings.

FIG. 1 is a sectional side view of a conventional heat sink.

FIG. 2 is an exploded view of a heat sink according to a first preferred embodiment of the present invention.

FIG. 3 is a sectional side view of the heat sink according to the first preferred embodiment of the present invention.

FIG. 4 is a top view of the heat sink according to the first preferred embodiment of the present invention.

FIG. 5 is a curve illustrating the comparison of the performance of the heat sink according to the preferred embodiment of the present invention and the conventional heat sink.

FIG. 6 is a sectional side view of a heat sink according to a second preferred embodiment of the present invention.

FIG. 7 is a sectional side view of a heat sink according to a third preferred embodiment of the present invention.

FIG. 8 is a sectional side view of a heat sink according to a fourth preferred embodiment of the present invention.

FIG. 9 is a sectional side view of a heat sink according to a fifth preferred embodiment of the present invention.

FIG. 10 is a sectional side view of a heat sink according to a sixth preferred embodiment of the present invention.

### DETAILED DESRIPTION OF THE PREFERRED EMBODIMENTS

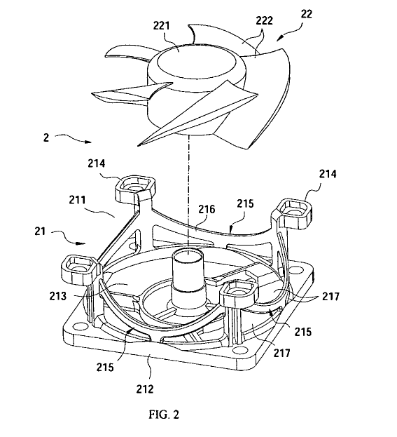

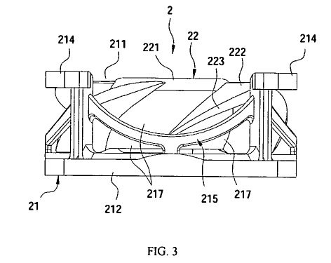

Referring to FIGS. 2 and 3, the heat sink 2 according to the first preferred embodiment of the present invention comprises a frame 21 including air inlets at a top side thereof and a fan 22 rotatably disposed in the frame 21. The fan 22 comprises a hub 221 rotatably and axially positioned at the central region of the frame 21 and a plurality of blades 222 alternately positioned around the outer periphery of the hub 221. In this embodiment, the blades 222 have a protruded arch-shape.

The frame 21 comprises a plate 212 including air inlets 213 and axially carry the hub 221 of the fan 22, four supporting elements 214 positioned correspondingly at the four corners flanges of the plate 212 and four ribs 215 positioned between the two supporting elements 214. The four supporting elements 214 correspond to each other to form air inlets 211 on a top side. Two adjacent supporting elements 214 form three side air inlets 217 with the corresponding the ribs 215 and one of the side air inlets 217 communicates with the top air inlets 211.

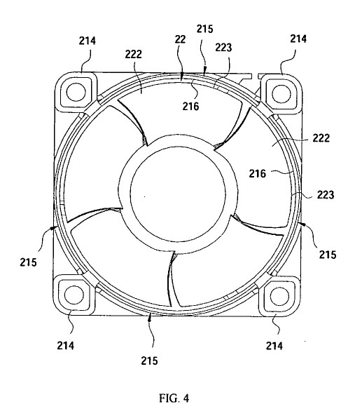

Referring to FIGS. 2 and 4, the supporting elements 214 and the ribs 215 have a round shape. Each rib 215 comprises an inner curved side 216 facing the fan 22. The flange 223 of the blades 222 is substantially parallel to the inner curved side 216 of the rib 215 when the blades 222 pass by the ribs 215. In this embodiment, the ribs 215 have an indented arch-shape.

When the fan 22 rotates, the air from outside enters via the top air inlets 211 and side air inlets 217, and the air from inside the frame 21 exits to outside via the air outlets 213 to dissipate the heat from the interior of the frame 21. When the air from outside enters via the side air inlets 217, the ribs 215 correspond with the blades 222 when the blades 222 pass by the ribs 215 and the flange 223 is substantially parallel to the inner curved side 216 of the rib 215, thus this arrangement guides the air from outside to enter via the side air inlets 217 and provides an excellent air circulation. Furthermore, because the ribs 215 have an indented arch-shape, there is no barricade between the side air inlets 217 and the top air inlets 211 and the frame 21 forms an open structure, and therefore the fan 22 is almost completely exposed to the incoming air and almost the whole surface area of the blades 222 form the air contact surface area. Thus, a substantially large volume of air from outside may be drawn into the frame 21 and also the noise level during the operation of the fan 22 may be effectively reduced.

Accordingly, the heat sink 2 of the present invention has at least the following advantages.

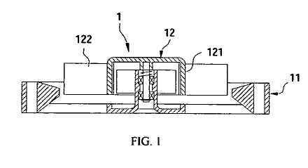

1. The overall volume of air entering from outside is obviously increased to enhance heat dissipation effect. Because the frame 21 is an open structure, the blades 222 of the fan 22 are completely exposed to the incoming air, and therefore the whole surface area of the blades 222 comes in contact with the air entering from the outside, and thus maximum quantity of the incoming air enters via the top air inlets 211 and the side air inlets 217. Furthermore, the inner curved side 216 of the rib 215 facilitates the passage of air from the side air inlets 217. The rib 215 corresponds with the blades 222 when the blades 222 pass by the ribs 215 and the flange 223 is substantially parallel to the inner curved side 216 of the rib 215, thus this arrangement guides the air from outside to enter via the side air inlets 217 and provides an excellent air circulation. Thus, a substantially large volume of air from outside may be drawn into the frame 21 and a substantially large volume of air may be exited to outside to substantially enhance the heat dissipation effect and thereby overcome the defects of the conventional heat sink 1 (shown in FIG. 1) having the partial hidden blades 122 with poor air passage effect that undesirably affect the air circulation.

2. To provide a better operating condition, it is important maintain an optimum static pressure such that the fan stalling region in the characteristic curve shown in FIG. 5 may be avoided, wherein the curve corresponds to the air volume and the air pressure, the continuous line represents the test performance result of the heat sink 2 of the present invention and the dotted line represents the test performance result of the conventional heat sink 1 where the air volume and the air pressure of the heat sink 2 is stable and linear. In other words, compared to the conventional heat sink 1, the heat sink 2 of the present invention can maintain an optimum static pressure avoiding the fan stalling region in order to provide the better operating condition (as shown by the shaded region in FIG. 5), and therefore the heat sink 2 of the present invention operates better than the conventional heat sink 1.

3. To effectively reduce the noise level during the operation of the fan, the present invention designs the frame 21 as an open structure so that the blades 222 of the fan are totally exposed to the outside, the inner curved side 216 of the ribs 215 facilitates the passage of the air from the outside via the side air inlets 217, and the flange 223 is substantially parallel to the inner curved side 216 of the ribs 215 when the blades 222 pass by the ribs 215 so that an excellent air circulation effect is achieved and the static pressure can maintained optimum to effectively reduce the noise level of the fan 22 to a range of about 4 to 5 dBA and thereby overcome the defects of the conventional heat sink 1 described above.

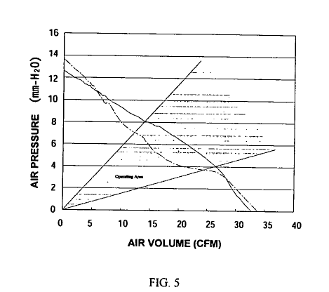

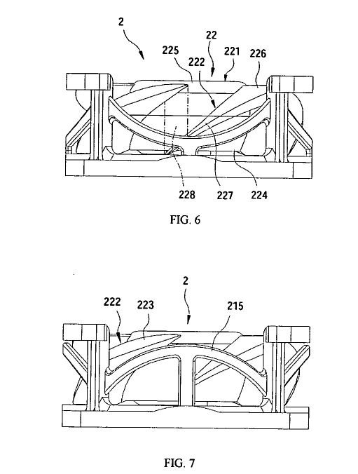

FIG. 6 shows the heat sink 2 according to a second preferred embodiment of the present invention, which is similar to that of the first embodiment described above, except for the hub 221 of the fan 22 comprises a lower hub 224 axially connected to the plate 212 and an upper hub 225 jointed to the top flange of the lower hub 224 by the bottom flange. Each blade 222 comprises an upper portion 226 positioned on the upper hub 225 and a lower portion 227 positioned on the lower hub 224, and the bottom flange of the upper portion 226 and the top flange of the lower portion 227 correspond to each other to form a complete arch leaf shape blades 222, and two adjacent blades 222 are stacked to form a guiding groove 228.

The stacked portion of the blades 222 increases the number of blades 222 positioned around the outer periphery of the hub 221, and the surface area of each blade 222 can be correspondingly increased to increase the overall surface area of the blades 222. Thus, the contact surface area between the incoming air and the blades 222 can be increased. In addition, the guiding groove 228 (indicated by the dotted line) increases the overall volumes of the incoming air and outgoing air to substantially promote the heat dissipation effect of the heat sink 2.

Therefore, compared to the heat sink 2 of the first embodiment, the heat sink 2 of the second embodiment, in addition to maintaining an optimum static pressure and low noise level, the volumes of the incoming air and outgoing air is substantially increased to substantially promote the heat dissipation effect of the heat sink 2.

FIG. 7 shows the heat sink 2 according to the third preferred embodiment of the present invention, which is similar to that of the first embodiment of the present invention described above, except for the ribs 215 have an arch-shape. Likewise, when the blades 222 pass by the ribs 215, the flange 223 of the blades 222 is parallel to the inner side of the ribs 215. Thus, the structure of the heat sink 2 of the third embodiment of the present invention can have a better heat dissipation effect as it can draw a substantially larger volume of air from outside and also maintain an optimum static pressure to effectively reduce the noise level during the operation of the fan 22.

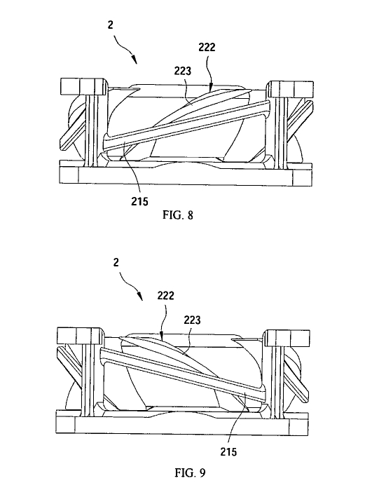

FIG. 8 shows the heat sink 2 according to the fourth preferred embodiment of the present invention, which is similar to that of the first embodiment of the present invention described above, except for the ribs 215 are inclined towards the left side. Likewise, when the blades 222 pass by the ribs 215, the flange 223 of the blades 222 is parallel to the inner side of the rib 215. Thus, the structure of the heat sink 2 of the fourth embodiment of the present invention can have a better heat dissipation effect as it can draw a substantially larger volume of air from outside and also maintain an optimum static pressure to effectively reduce the noise level during the operation of the fan 22.

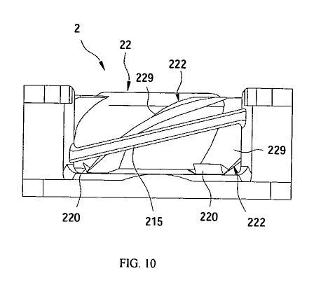

FIG. 9 shows the heat sink 2 according to the fifth embodiment of the present invention, which is similar to that of the first embodiment of the present invention described above, except for the ribs 215 are inclined towards the right side and the blades 222 are inclined from left to right side. Likewise, when the blades 222 pass by the ribs 215, the flange 223 of the blades 222 is parallel to the inner side of the rib 215. Thus, the structure of the heat sink 2 of the fifth embodiment of the present invention can have a better heat dissipation effect as it can draw a substantially larger volume of air from outside and also maintain an optimum static pressure to effectively reduce the noise level during the operation of the fan 22.

FIG. 10 shows the heat sink 2 according to the sixth preferred embodiment of the present invention, which is similar to that of the first embodiment of the present invention, except for each of the blades 222 of the fan 22 comprises an arch element 229 and a triangular element 220 vertically protruding from the bottom of the arch element 229. Generally, the shape of the blades 222 is similar to a wing shape of the pterodactyl.

Likewise, when the blades 222 pass by the ribs 215, the flange 223 of the blades 222 is parallel to the inner side of the rib 215. Thus, the structure of the heat sink 2 of the sixth embodiment of the present invention can have a better heat dissipation effect as it can draw a substantially larger volume of air from outside and also maintain an optimum static pressure to effectively reduce the noise level during the operation of the fan 22.

In summary, the heat sink 2 comprises the open frame 21 to facilitate influx of a substantially large volume air from outside into the frame 21 via the top air inlets 211 and the side air inlets 217 when the fan 22 rotates and thereby effectively increase the volume of incoming air and also substantially reduce the noise level during the operation of the fan 22. Meanwhile, when the blades 222 pass by the ribs 215, the flange 223 of the blades 222 is parallel to the top face 216 and the inner curved side 218 of the rib 215 to facilitate the passage of substantially large volume of air from outside and thereby promote the heat dissipation effect and also maintain an optimum static pressure.

While the invention has been described in conjunction with a specific best mode, it is to be understood that many alternatives, modifications, and variations will be apparent to those skilled in the art in light of the foregoing description. Accordingly, it is intended to embrace all such alternatives, modifications, and variations in which fall within the spirit and scope of the included claims. All matters set forth herein or shown in the accompanying drawings are to be interpreted in an illustrative and non-limiting sense.

What is claimed is:

1. A heat sink, comprising
a frame, including at least a top air inlet, comprising a plate including at least an air outlet, a plurality of supporting elements alternately positioned at a flange of the plate and a plurality of ribs positioned between two adjacent supporting elements, wherein each rib comprises an inner curved side, and wherein said supporting elements and said ribs correspond to each other to form a plurality of air inlets; and
a fan, rotatably disposed in said frame, comprising a hub rotatably and axially positioned over said plate, and a plurality of blades alternately positioned around an outer periphery of said hub, wherein a flange of said blades is substantially parallel to said inner curved side of said ribs when said blades pass by the ribs.

2. The heat sink according to claim 1, wherein said ribs of said frame have an indented arch-shape, and a distal end and a primal end of said ribs are jointed to two corresponding adjacent supporting elements.

3. The heat sink according to claim 1, wherein said ribs of said frame have a protruded arch-shape, and a distal end and a primal end of said ribs are jointed to two corresponding adjacent supporting elements.

4. The heat sink according to claim 1, wherein said ribs of said frame are inclined towards the left side, and a distal end and a primal end of said ribs are jointed to two corresponding adjacent supporting elements.

5. The heat sink according to claim 1, wherein said ribs of said frame are inclined towards the right side, and a distal end and a primal end of said ribs are jointed to two corresponding adjacent supporting elements.

6. The heat sink according to claim 1, wherein said blades of said fan have an arch-shape.

7. The heat sink according to claim 1, wherein said blades of said fan comprise an arch element and a triangular element vertically protruding from a bottom of said arch element.

8. The heat sink according to claim 1, wherein said hub of said fan comprises a lower hub axially connected to said plate and an upper hub jointed to a top flange of said lower hub by a bottom flange, and wherein each blade comprises an upper portion positioned on said upper hub and a lower portion positioned on said lower hub, and said bottom flange of said upper portion and said top flange of said lower portion correspond to each other to form a leaf shaped lower blades, and two adjacent blades are stacked to form a guiding groove.
